(19) United States
(12) Patent Application Publication
(10) Pub. No.: US 2020/0084847 A1
(43) Pub. Date: Mar. 12, 2020

(54) Pulse Width Modulation Circuit

(71) Applicant: Dialog Semiconductor (UK) Limited, London (GB)

(72) Inventors: Nailong Wang, Beijing (CN); Xiaogang Zhao, Beijing (CN); Lingxin Kong, Beijing (CN); Libo Zhou, Beijing (CN)

(21) Appl. No.: 16/185,126

(22) Filed: Nov. 9, 2018

(30) Foreign Application Priority Data
Sep. 12, 2018 (CN) 201821489369.3

(51) Int. Cl. H05B 33/08; H02M 1/08; H03K 7/08

(52) U.S. Cl. CPC H05B 33/0818; H05B 33/0851; H02M 2001/0009; H03K 7/08; H02M 1/08

(57) ABSTRACT

A pulse width modulation (PWM) circuit and method are presented. The circuit has a switch for repeatedly coupling and decoupling a circuit element to a current source. The circuit also has feedback circuitry to detect a current flowing through the circuit element. The circuit also has a PWM generator to provide a digital signal to the switch and to adjust the digital signal in response to the detected current.

This application claims priority to China application 2018214893693, filed Sep. 12, 2018, which is herein incorporated by reference in its entirety.

### TECHNICAL FIELD

The present disclosure relates to a pulse width modulation (PWM) circuit. In particular the disclosure relates to a PWM circuit to compensate for unwanted circuit effects that result in a mismatch between a target current waveform and the actual current waveform through a circuit element. In particular, the present disclosure may be applied in PWM dimming in light emitting diode (LED) backlighting applications.

### BACKGROUND

The pulse width modulation (PWM) dimming method has been widely used in light emitting diode (LED) backlighting applications. FIG. 1(a) is a schematic of an LED circuit 100 suitable for use in LED backlighting applications. The LED circuit 100 comprises a current source 102 a dimming transistor 104 and an LED string 106, where the LED string 106 comprises three LEDs 108. The LED string 106 has a first terminal coupled to a DC-DC converter 110, that provides an LED voltage Vled, and has a second terminal coupled to a first terminal of the dimming transistor 104. A second terminal of the dimming transistor 104 is coupled to the current source 102.

In operation, the dimming transistor 104 receives a PWM signal PWM-sig at its gate. The PWM signal PWM-sig is a digital signal that repeatedly switches between high and low states. Upon receiving a high state at its gate, the dimming transistor 104 couples the LED string 106 to the current source 102, and the LED string 106 is “turned on” and illuminated. Upon receiving a low state at its gate, the dimming transistor 104 decouples the LED string 106 from the current source 102, and the LED string 106 is “turned off” and the LED string 106 is not illuminated.

Repeated enabling and disabling of the dimming transistor 104 using the PWM signal PWM-sig at a sufficiently high frequency can provide the appearance of dimming of the light provided by the LED string 106. The LED string 106 may be dimmed by decreasing the duty cycle of the PWM signal PWM-sig, with the maximum level of illumination of the LED string 106 being provided at a duty cycle of one.

FIG. 1(b) is a schematic of an LED circuit 112 corresponding to the LED circuit 100, but with a specific implementation of the current source 102 shown. The current source 102 comprises a current regulator 114 comprising an operational amplifier 116, a regulator transistor 118 and a setting resistor 120. The operational amplifier 116 is coupled to a reference voltage Vref. Common features between the LED circuit 100 and the LED circuit 112 are represented by common reference numerals and common variables. A node Ns is coupled to an input of the operational amplifier 116, a terminal of the regulator transistor 118 and the setting resistor 120.

FIG. 2 shows simulation results relating to the LED circuit 112. The simulations were performed using parameters that are representative of a practical implementation of the LED circuit 112. Shown in FIG. 2 is a PWM waveform 200, a voltage waveform 202 and a current waveform 203. The PWM waveform 200 has a rising edge 204 at a time t1 and has a falling edge 206 at a time t2.

The PWM waveform 200 shows the PWM signal PWM-sig that is received at the gate of the dimming transistor 104 as it varies with time. The voltage waveform 202 shows a node voltage Vs at the node Ns as it varies with time. The current waveform 203 shows a current Iled as it varies with time. The current Iled that flows through the LED string 106 is given by equation (1), as follows:

$$Iled = \frac{Vs}{Rs} \qquad ( 1 )$$

where Rs is the resistance of the setting resistor 120.

Therefore, the voltage waveform 202 has the same profile as the current waveform 203. The current waveform 203 shows the current Iled that flows through the LED string 106 as the PWM signal PWM-sig repeatedly couples and decouples the current source 102 and the LED string 106. The term “profile” here is used to describe the shape of the waveforms.

It can be observed in FIG. 2 that the profiles of the PWM waveform 200 and the current waveform 203 do not match.

The mismatch between the shapes of the PWM waveform 200 and the current waveform 203 is a result of unwanted properties of the LED circuit 112, such as parasitic resistances and parasitic capacitances.

When comparing the profiles of the PWM waveform 200 and the current waveform 203 the following factors are considered: a turn on delay, a turn off delay, a rising time and a falling time.

Two waveforms having the same profile will have no turn on or off delays between them, and will have equal rising times and equal falling times.

The turn on delay may be defined as the time taken from the PWM rising edge 204 until the current Iled reaches half of its peak value. The peak value of the current Iled is indicated by reference numeral 208 on FIG. 2. The turn off delay may be defined as the time taken from the PWM falling edge 206 until the current Iled reaches half of its peak value. The rising time may be defined as the time taken for the current Iled to increase from 10% of its peak value to 90% of its peak value. The falling time may be defined as the time taken for the current Iled to decrease from 90% of its peak value to 10% of its peak value. As the current Iled relates to the node voltage Vs by equation (1), the current Iled is at its peak value when the node voltage Vs is at its peak value. A pulse width 210 of the current waveform 203 may be defined as a time period from when the current Iled is at half of its peak value as the current Iled rises, until it returns to half of its peak value as the current Iled falls.

It will be appreciated that the turn on delay, the turn off delay, the rising time, the falling time and the pulse width may otherwise be defined in accordance with the understanding of the skilled person. For example, the turn on delay may alternatively be defined as the time taken from the PWM rising edge 204 until the current Iled reaches three quarters of its peak value.

Although it is not essential to provide a current waveform 203 that matches the profile of the PWM waveform 200, for LED backlighting applications it is desirable to have a current waveform 203 that provides one or more of the following properties: a well-controlled and accurate average current Iled over a time period; a well-controlled and accurate pulse width 210; and well-controlled and accurate timing characteristics.

However, these parameters are typically not well-controlled and accurate due to unwanted characteristics of the LED circuit 112, such as the parasitic capacitances and resistances.

A high precision current waveform 203 with one or more of the aforementioned properties is becoming a critical requirement in backlighting applications, for example for TV/monitors and mobile applications where it is desirable to have high contrast ratio. This is especially true for low duty cycles, for example for a pulse width of 1 μs.

Prior art methods are incapable of generating a suitable current waveform due to turn on/off delays and rising/falling times, that result from the parasitic capacitances and resistances, as discussed above. The parasitic capacitances and parasitic resistance may arise due to the dimming transistor 104. The dimming transistor 104 may be implemented as an internal or external MOSFET. Additionally, the shape of the rising and falling current waveform 203 can adversely impact precision.

### SUMMARY

It is desirable to provide a PWM circuit for PWM dimming applications that can provide a current waveform that provides one or more of the following properties: a well-controlled and accurate average current over a time period; a well-controlled and accurate pulse width; and well-controlled and accurate timing characteristics.

According to a first aspect of the disclosure there is provided a pulse width modulation (PWM) circuit, comprising a switch for repeatedly coupling and decoupling a circuit element to a current source, feedback circuitry configured to detect a current flowing through the circuit element, and a PWM generator configured to provide a digital signal to the switch and to adjust the digital signal in response to the detected current.

Optionally, the current source is configured to provide the current to the circuit element when the current source and the circuit element are coupled, the digital signal comprises a first state and a second state, the switch is arranged to couple the circuit element to the current source when the digital signal is in the first state, and the switch is arranged to decouple the circuit element from current source when the digital signal is in the second state.

Optionally, the switch is a dimming transistor comprising a gate coupled to the PWM generator, wherein the digital signal is received at the gate of the dimming transistor.

Optionally, the circuit element comprises at least one light emitting diode (LED).

Optionally, the current source comprises a current regulator.

Optionally, the current regulator comprises an operational amplifier, a regulator transistor, and a setting resistor, wherein the operational amplifier has a first input coupled to a reference voltage, a second input coupled to a terminal of the regulator transistor at a node and an output coupled to a gate of the regulator transistor, and the setting resistor has a first terminal coupled to the node and a second terminal coupled to ground.

Optionally, the feedback circuitry is configured to detect the current flowing through the circuit element by detecting the current at the node.

Optionally, the feedback circuitry is configured to detect the current at the node by detecting a node voltage at the node.

Optionally, the feedback circuitry is configured to detect the current flowing through the circuit element by detecting a gate voltage at the gate of the regulator transistor.

Optionally, the PWM generator is configured to adjust the digital signal based on the outcome of a comparison between a property of the detected current and a target value.

Optionally, the feedback circuitry comprises a comparator for performing the comparison by comparing a signal that is representative of the property of the detected current with the target value.

Optionally, the property of the detected current is the average of the detected current.

Optionally, the feedback circuitry comprises an integrator circuit configured to provide the signal that is representative of the average detected current to the comparator.

Optionally, the current source comprises a current regulator.

Optionally, the current regulator comprises an operational amplifier, a regulator transistor, and a setting resistor, wherein the operational amplifier has a first input coupled to a first reference voltage, a second input coupled to a terminal of the regulator transistor at a node and an output coupled to a gate of the regulator transistor, and the setting resistor has a first terminal coupled to the node and a second terminal coupled to ground.

Optionally, the feedback circuitry is configured to detect the current flowing through the circuit element by detecting the current at the node.

Optionally, the feedback circuitry is configured to detect the current at the node by detecting a node voltage at the node, and the integrator circuit is configured to receive the node voltage.

Optionally, the property of the detected current is a pulse width.

Optionally, the current source comprises a current regulator.

Optionally, the current regulator comprises an operational amplifier, a regulator transistor, and a setting resistor, wherein the operational amplifier has a first input coupled to a first reference voltage, a second input coupled to a terminal of the regulator transistor at a node and an output coupled to a gate of the regulator transistor, and the setting resistor has a first terminal coupled to the node and a second terminal coupled to ground.

Optionally, the feedback circuitry is configured to detect the current flowing through the circuit element by detecting the current at the node.

Optionally, the feedback circuitry is configured to detect the current at the node by detecting a node voltage at the node.

Optionally, the feedback circuitry comprises a comparator for comparing the node voltage with a second reference voltage to provide a signal suitable for determination of the pulse width.

Optionally, the property of the detected current is a turn on delay.

Optionally, the current source comprises a current regulator.

Optionally, the current regulator comprises an operational amplifier, a regulator transistor, and a setting resistor, wherein the operational amplifier has a first input coupled to a first reference voltage, a second input coupled to a terminal of the regulator transistor at a node and an output coupled to a gate of the regulator transistor, and the setting resistor has a first terminal coupled to the node and a second terminal coupled to ground.

Optionally, the feedback circuitry is configured to detect the current flowing through the circuit element by detecting the current at the node.

Optionally, the feedback circuitry is configured to detect the current at the node by detecting a node voltage at the node.

Optionally, the feedback circuitry comprises a comparator for comparing the node voltage with a second reference voltage to provide a signal suitable for determination of the turn on delay.

Optionally, the feedback circuitry is configured to detect the current flowing through the circuit element by detecting a gate voltage at the gate of the regulator transistor.

Optionally, the feedback circuitry comprises a comparator for comparing the gate voltage with a third reference voltage to provide a signal suitable for determination of the turn on delay.

Optionally, the PWM generator is configured to adjust the digital signal using a property of the detected current, the property of the detected current being a turn on delay.

Optionally, the feedback circuitry comprises a comparator for comparing the gate voltage with a third reference voltage to provide a signal suitable for determination of the turn on delay.

Optionally, the PWM generator is configured to adjust the digital signal by doing at least one of the following increasing a high time of the digital signal, decreasing the high time of the digital signal, increasing a delay time of the digital signal, and decreasing the delay time of the digital signal.

According to a second aspect of the disclosure there is provided a method of operating a pulse width modulation (PWM) circuit, comprising repeatedly coupling and decoupling a circuit element to a current source using a switch, detecting a current flowing through the circuit element using feedback circuitry, and providing a digital signal to the switch and adjusting the digital signal in response to the detected current using a PWM generator.

Optionally, the digital signal comprises a first state and a second state, the method comprising providing the current from the current source to the circuit element when the current source and the circuit element are coupled, coupling the circuit element to the current source using the switch when the digital signal is in the first, and decoupling the circuit element from current source using the switch when the digital signal is in the second state.

Optionally, the switch is a dimming transistor comprising a gate coupled to the PWM generator, the method comprising receiving the digital signal at the gate of the dimming transistor.

Optionally, the circuit element comprises at least one light emitting diode (LED).

Optionally, the current source comprises a current regulator.

Optionally, the current regulator comprises an operational amplifier, a regulator transistor, and a setting resistor, wherein the operational amplifier has a first input coupled to a reference voltage, a second input coupled to a terminal of the regulator transistor at a node and an output coupled to a gate of the regulator transistor, and the setting resistor has a first terminal coupled to the node and a second terminal coupled to ground.

Optionally, the method comprises detecting the current flowing through the circuit element by detecting the current at the node using the feedback circuitry.

Optionally, the method comprises detecting the current at the node by detecting a node voltage at the node using the feedback circuitry.

Optionally, the method comprises detecting the current flowing through the circuit element by detecting a gate voltage at the gate of the regulator transistor using the feedback circuitry.

Optionally, the method comprises adjusting the digital signal based on the outcome of a comparison between a property of the detected current and a target value using the PWM generator.

Optionally, the feedback circuitry comprises a comparator, the method comprising performing the comparison by comparing a signal that is representative of the property of the detected current with the target value using the comparator.

Optionally, the property of the detected current is the average of the detected current.

Optionally, the feedback circuitry comprises and integrator circuit, the method comprising providing the signal that is representative of the average detected current to the comparator using the integrator circuit.

Optionally, the current source comprises a current regulator.

Optionally, the current regulator comprises an operational amplifier, a regulator transistor, and a setting resistor, wherein the operational amplifier has a first input coupled to a first reference voltage, a second input coupled to a terminal of the regulator transistor at a node and an output coupled to a gate of the regulator transistor, and the setting resistor has a first terminal coupled to the node and a second terminal coupled to ground.

Optionally, the method comprises detecting the current flowing through the circuit element by detecting the current at the node using the feedback circuitry.

Optionally, the method comprises detecting the current at the node by detecting a node voltage at the node using the feedback circuitry, and receiving the node voltage at the integrator circuit.

Optionally, the property of the detected current is a pulse width.

Optionally, the current source comprises a current regulator.

Optionally, the current regulator comprises an operational amplifier, a regulator transistor, and a setting resistor, wherein the operational amplifier has a first input coupled to a first reference voltage, a second input coupled to a terminal of the regulator transistor at a node and an output coupled to a gate of the regulator transistor, and the setting resistor has a first terminal coupled to the node and a second terminal coupled to ground.

Optionally, the method comprises detecting the current flowing through the circuit element by detecting the current at the node using the feedback circuitry.

Optionally, the method comprises detecting the current at the node by detecting a node voltage at the node using the feedback circuitry.

Optionally, the feedback circuitry comprises a comparator, the method comprising comparing the node voltage with a second reference voltage to provide a signal suitable for determination of the pulse width using the comparator. Optionally, the property of the detected current is a turn on delay.

Optionally, the current source comprises a current regulator.

Optionally, the current regulator comprises an operational amplifier, a regulator transistor, and a setting resistor, wherein the operational amplifier has a first input coupled to a first reference voltage, a second input coupled to a terminal of the regulator transistor at a node and an output coupled to a gate of the regulator transistor, and the setting resistor has a first terminal coupled to the node and a second terminal coupled to ground.

Optionally, the method comprises detecting the current flowing through the circuit element by detecting the current at the node using the feedback circuitry.

Optionally, the method comprises detecting the current at the node by detecting a node voltage at the node using the feedback circuitry.

Optionally, the feedback circuitry comprises a comparator, the method comprising comparing the node voltage with a second reference voltage to provide a signal suitable for determination of the turn on delay using the comparator.

Optionally, the method comprises detecting the current flowing through the circuit element by detecting a gate voltage at the gate of the regulator transistor using the feedback circuitry.

Optionally, the feedback circuitry comprises a comparator, the method comprising comparing the gate voltage with a third reference voltage to provide a signal suitable for determination of the turn on delay using the comparator.

Optionally, the method comprises adjusting the digital signal using a property of the detected current using the PWM generator, wherein the property of the detected current is a turn on delay.

Optionally, the feedback circuitry comprises a comparator, the method comprising comparing the gate voltage with a third reference voltage to provide a signal suitable for determination of the turn on delay using the comparator.

Optionally, the method comprises adjusting the digital signal using the PWM generator by doing at least one of the following increasing a high time of the digital signal, decreasing the high time of the digital signal, increasing a delay time of the digital signal, and decreasing the delay time of the digital signal.

### BRIEF DESCRIPTION OF THE DRAWINGS

The disclosure is described in further detail below by way of example and with reference to the accompanying drawings, in which:

FIG. 1A is a schematic of a first prior art LED circuit and FIG. 1B is a schematic of a second prior art LED circuit;

FIG. 2 shows simulation results relating to the LED circuit shown in FIG. 1B;

FIG. 3A is a schematic of an apparatus in accordance with a first embodiment of this disclosure, FIG. 3B is a schematic of an LED circuit in accordance with a second embodiment of this disclosure, and FIG. 3C is a schematic of an LED circuit in accordance with a third embodiment of this disclosure;

FIG. 4 is a schematic of an LED circuit in accordance with a fourth embodiment of this disclosure;

FIG. 5 is a layout of the simulation of the LED circuit of FIG. 4;

FIG. 6 shows simulation results relating to the LED circuit shown in FIG. 4;

FIG. 7 is a schematic of an LED circuit in accordance with a fifth embodiment of this disclosure;

FIG. 8 shows simulation results relating to the LED circuit shown in FIG. 7;

FIG. 9 is a graph showing waveforms relating to the operation of two LED circuits of the type shown in FIG. 7;

FIG. 10 is a schematic of an LED circuit in accordance with a sixth embodiment of this disclosure; and

FIG. 11 shows simulation results relating to the LED circuit shown in FIG. 10.

### DESCRIPTION

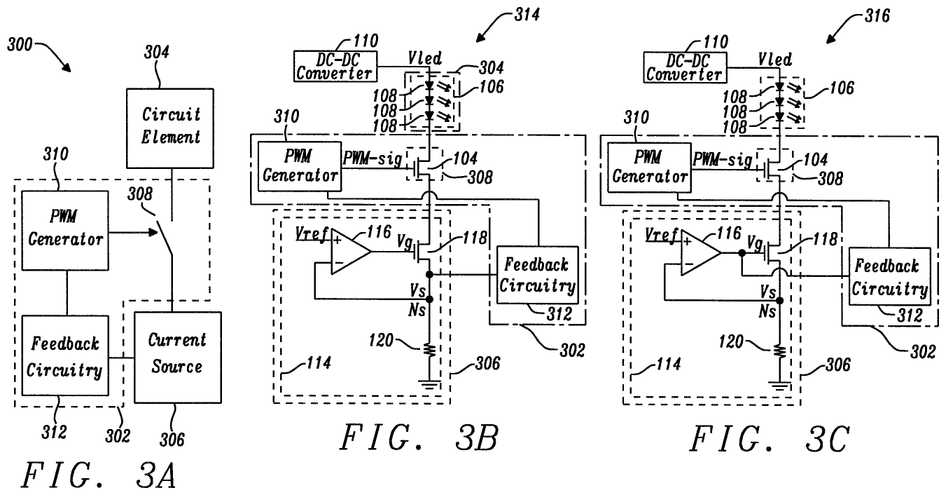

FIG. 3A is a schematic of an apparatus 300 comprising a pulse width modulation (PWM) circuit 302, a circuit element 304 and a current source 306 in accordance with a first embodiment of this disclosure. The PWM circuit 302 may alternatively be referred to as a PWM dimming driver.

The PWM circuit 302 comprises a switch 308, a PWM generator 310 and feedback circuitry 312. The switch 308 has a first terminal coupled to the circuit element 304 and a second terminal coupled to the current source 306. The switch 308 is suitable for repeatedly coupling and decoupling the circuit element 304 to the current source 306.

The PWM generator 310 is configured to provide a digital signal to the switch 308. The current source 306 is configured to provide a current to the circuit element 304 when they are coupled. The digital signal comprises a first state and a second state. The switch 308 is arranged to couple the circuit element 304 to the current source 306 when the digital signal is in the first state and the switch 308 is arranged to decouple the circuit element 304 from current source 306 when the digital signal is in the second state.

The feedback circuitry 312 is configured to detect the current flowing through the circuit element 304 and the PWM generator 310 is configured to adjust the digital signal in response to the detected current.

Adjusting the digital signal will alter the current flowing through the circuit element 304. Therefore, the adjustment of the digital signal may be used to adjust a property of the current flowing through the circuit element 304. The property may be the average of the detected current over a time period, the pulse width of the current waveform or the timing characteristics of the current waveform. The timing characteristics may refer to the turn on delay and/or the turn off delay as described previously.

Therefore, adjusting the digital signal may be used to do one or more of the following: adjusting the average current, adjusting the pulse width of the associated current waveform, and adjusting the timing characteristics.

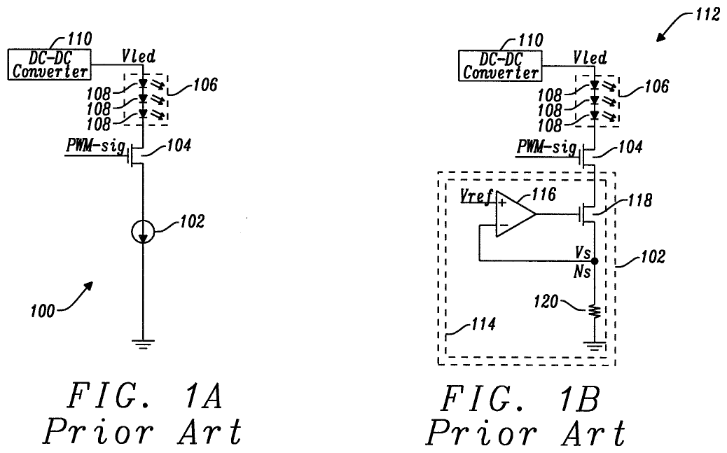

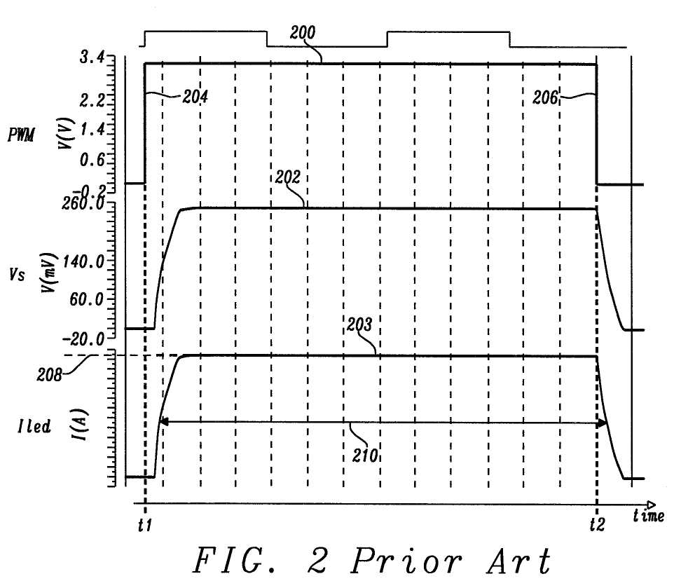

Therefore, by using the apparatus 300 it is possible to provide a well-controlled and accurate average current, a well-controlled and accurate pulse width and well-controlled and accurate timing characteristics by compensating for the characteristics of the circuit, such as parasitic parameters, that can result in an imprecise current waveform, as discussed previously for FIGS. 1 and 2.

In operation, the feedback circuitry 312 provides a closed compensation loop by detecting the current through the circuit element 304 and providing a signal to the PWM generator 310. The PWM generator 310 may adjust the digital signal based on the outcome of a comparison between a property of the detected current and a target current property, which may be referred to as a target value.

The target value may be, for example, a target average current, a target high time setting, a target pulse width or a target delay time. The target values may be associated with a target current waveform.

Based on the comparison between the property of the detected current and a target current property, a suitable adjustment to the digital signal is applied to achieve the target current property.

The digital signal can be accurately controlled by digital logic and the target current property may be set by a user. The target current property may be derived from the digital signal.

Alternatively, the digital signal may be adjusted using a property of the detected current, without there being a requirement for a comparison of the property of the detected current with a target value.

FIG. 3B is a schematic of an LED circuit 314 in accordance with a second embodiment of this disclosure. The LED circuit 314 comprises the LED circuit 112 of FIG. 1B and the PWM circuit 302. Common features between the LED circuit 100, the LED circuit 112, the apparatus 300 and the LED circuit 314 are represented by common reference numerals and common variables.

The digital signal output by the PWM generator 310 corresponds to the PWM signal PWM-sig as described previously.

The switch 308 is the dimming transistor 104, as previously described. The dimming transistor 104 comprises a gate coupled to the PWM generator 310 and the PWM signal PWM-sig is received at the gate of the dimming transistor 104.

The circuit element 304 comprises the LED string 106, which comprises the three LEDs 108. It will be appreciated that the circuit element 304 may comprise a single LED or an LED string comprising a plurality of LEDs. Alternatively, the circuit element 304 may comprise any other suitable component in accordance with the understanding of the skilled person.

The current source 306 comprises the current regulator 114, as described previously. The current regulator 114 comprises the operational amplifier 116, the regulator transistor 118 and the setting resistor 120.

The operational amplifier 116 has a first input coupled to a reference voltage Vref, a second input coupled to a terminal of the regulator transistor 118 at a node Ns, and an output coupled to a gate of the regulator transistor 118. The node Ns is at the node voltage Vs. Another terminal of the regulator transistor 118 is coupled to the second terminal of the dimming transistor 104. The setting resistor 120 has a first terminal coupled to the node Ns and a second terminal coupled to ground.

The feedback circuitry 312 is coupled to the node Ns. The current Iled, corresponding to the current flowing through the LED string 106 is detected at the node Ns by detecting the node voltage Vs. The current Iled and the node voltage Vs are related by equation (1) as discussed previously. Detecting the current Iled by detecting the node voltage Vs may be referred to as sensing the current Iled.

FIG. 3C is a schematic of an LED circuit 316 in accordance with a third embodiment of this disclosure. The LED circuit 316 comprises the LED circuit 112 of FIG. 1B and the PWM circuit 302. Common features between the LED circuit 100, the LED circuit 112, the apparatus 300 and the LED circuit 316 are represented by common reference numerals and common variables.

The LED circuit 316 is as described for the LED circuit 314, however rather than having the feedback circuitry 312 coupled to the node Ns, the feedback circuitry is coupled to the gate of the regulator transistor 118. The current Iled is detected by detecting a gate voltage Vg at the gate of the regulator transistor 118.

It will be appreciated that “detecting” the current Iled may refer to a precise measurement of the current Iled or may alternatively refer to detecting a property of the current Iled, or detecting the presence of the current Iled, without having a precise and/or direct measurement of the current Iled.

As the gate voltage Vg at the gate of the regulator transistor 118 can be indicative that the current Iled is being provided by the current regulator 114 to the LED string 106, detecting the gate voltage Vg at the gate of the regulator transistor 118 may be considered a means of detecting the current Iled.

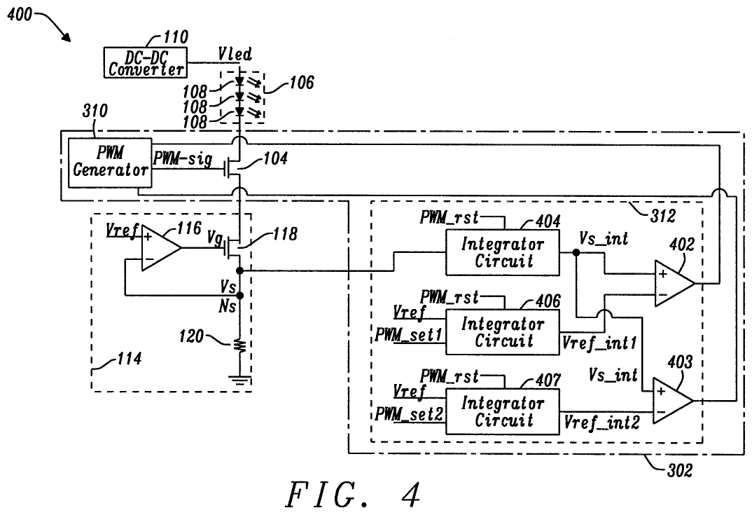

FIG. 4 is a schematic of an LED circuit 400 in accordance with a fourth embodiment of this disclosure. The LED circuit 400 corresponds to the LED circuit 314 with a specific implementation of the feedback circuitry 312 shown. Common features between different Figures are represented by common reference numerals and common variables.

The feedback circuitry 312 comprises at least one comparator for comparing a signal that is representative of a property of the detected current Iled with at least one target value. The PWM generator 310 then adjusts the PWM signal PWM-sig based on the outcome of the comparison.

In the present embodiment there are two target values Vref_int1, Vref_int2 and two comparators 402, 403. The PWM generator 310 adjusts the PWM signal PWM-sig based on the outcome of the comparisons.

In this specific example, the property of the detected current Iled is the average of the detected current Iled. In operation the average of the current Iled is compared with a target average current and the PWM signal PWM-sig is adjusted to provide the target average current.

The feedback circuitry 312 further comprises an integrator circuit 404 that is configured to provide the signal that is representative of the average of the detected current Iled to the comparators 402, 403. The node Ns is coupled to an input of the integrator circuit 404 and therefore the node voltage Vs is provided to the integrator circuit 404. The current Iled is detected by detecting the node voltage Vs.

The integrator circuit 404 receives the node voltage Vs, integrates the node voltage Vs over a time period, and outputs a signal Vs_int that is representative of the average of the detected current Iled. In this embodiment, the signal Vs_int may be referred to as the integrated signal. The integrated signal Vs_int is provided to an input of the comparator 402 and an input of the comparator 403.

The integrated signal Vs_int is determined periodically with each period of the PWM signal PWM-sig. The integrator circuit 404 receives a reset signal PWM_rst that periodically resets the integrator circuit 404 after each period of the PWM signal PWM-sig. Therefore, the integrated signal Vs_int is indicative of the average detected current Iled for each period of the PWM signal PWM-sig.

The integrated signal Vs_int is compared with at least one target value that relates to the target average current, to determine whether the average detected current Iled is greater or less than a target average current. A compensation factor can then be determined and applied to the PWM signal PWM-sig to adjust the PWM signal PWM_sig and to bring the average detected current Iled closer to the target average current.

In this specific embodiment there are two target values Vref_int1, Vref_int2, where Vref_int1 is provided to an input of the comparator 402 and Vref_int2 is provided to an input of the comparator 403. The target values Vref_int1, Vref_int2 may be provided directly to the inputs of their respective comparators 402, 403 or alternatively may be generated using another method. In the specific embodiment shown in FIG. 4, the feedback circuitry 312 comprises an integrator circuit 406 and an integrator circuit 407 configured to generate the target values Vref_int1 and Vref_int2, respectively.

The duration of time over which a digital signal is in a high state may be referred to as its high time. The high time PWM_HT_DIG of the PWM signal PWM-sig of the LED circuit 400 is given by equation (2):

PWM_HT_DIG=PWM_HT_SET+PWM_HT_COMP (2)

where PWM_HT_SET is a target high time setting of the PWM signal PWM-sig, as may be set by a user, and PWM_HT_COMP is a compensation signal that is generated based on the comparisons between the integrated signal Vs_int and the target values Vref_int1, Vref_int2.

The reference voltage Vref is the target value of the node voltage Vs and is related to a target current Iref by equation (3):

$$Iref = \frac{Vref}{Rs} \qquad ( 3 )$$

The target value Vref_int1 is a lower threshold value and is generated by multiplying the reference voltage Vref by PWM_set1 and integrating the result using the integrator circuit 406. The target value Vref_int2 is an upper threshold value and is generated by multiplying the reference voltage Vref by PWM_set2 and integrating the result using the integrator circuit 407. PWM_set1 and PWM_set2 are given by equations (4) and (5), respectively:

PWM_set1=PWM_HT_SET−PWM_n1 (4)

PWM_set2=PWM_HT_SET+PWM_n2 (5)

where PWM_n1 and PWM_n2 are offset values. The offset values PWM_n1, PWM_n2 should be suitable for providing suitable target values Vref_int1, Vref_int2 for the present application in accordance with the understanding of the skilled person. The offset values PWM_n1 and PWM_n2 may be equal and may, for example, both be equal to one.

The target values Vref_int1 and Vref_int2 are representative of a lower target average current and an upper target average current, respectively. A further embodiment comprising a single comparator may have a single target value Vref_int that is representative of the target average current.

In operation the integrated signal Vs_int is compared with the target values Vref_int1, Vref_int2 every period of the PWM signal PWM-sig. Then the compensation signal PWM_HT_COMP may be adjusted as follows.

If Vs_int>Vref_int2 then decrease PWM_HT_COMP; if Vs_int<Vref_int1 then increase PWM_HT_COMP; and if Vref_int1<Vs_int<Vref_int2 keep PWM_HT_COMP at its present value.

This specific embodiment can provide an accurate average detected current Iled, that matches a target average current, by adjusting the high time of the PWM signal PWM-sig. As such, it is not essential to alter the specific profile of the current waveform and the associated turn off/turn on delays and rising/falling times to provide the target average current.

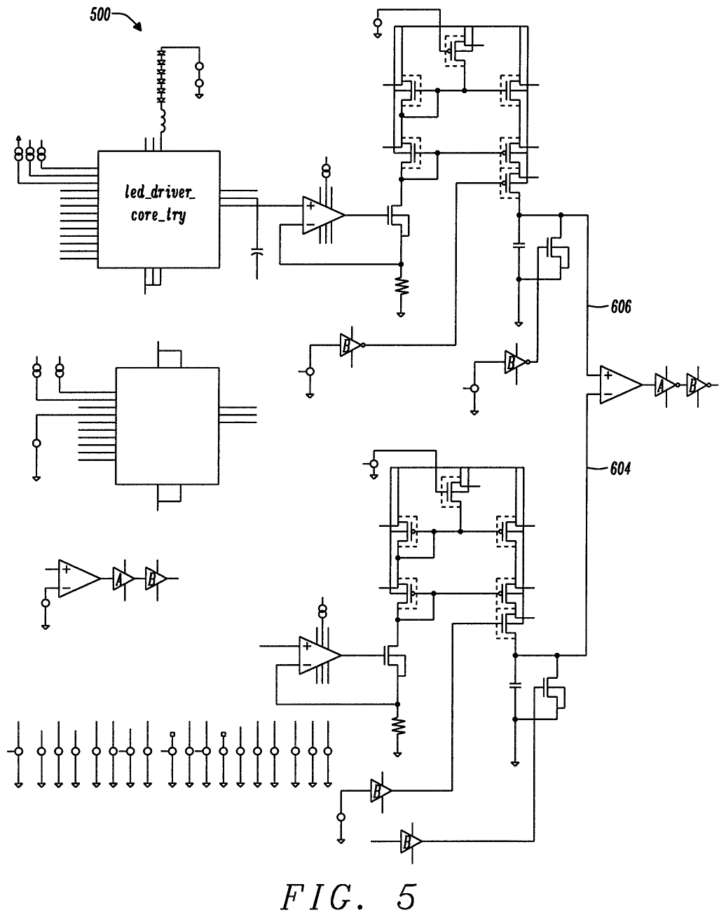

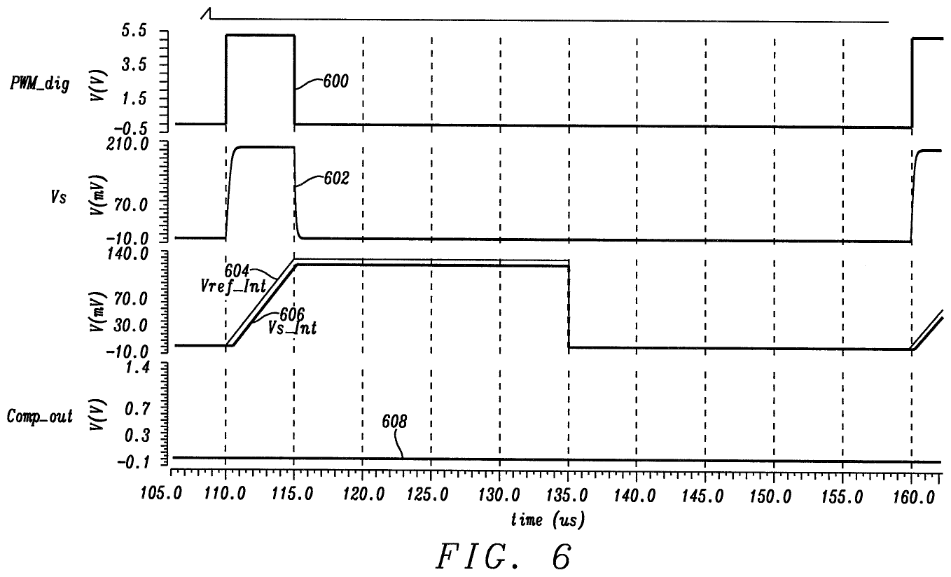

FIG. 5 shows a layout 500 of the simulation of the LED circuit 400 as shown in FIG. 4. FIG. 6 shows simulation results relating to the LED circuit 400. The simulations were performed using parameters that are representative of a practical implementation of the LED circuit 400. Shown in FIG. 6 is the PWM signal PWM-sig 600, the node voltage Vs 602, the target value Vref_int1 604, the integrated signal Vs_int 606 and an output 608 of the comparator 402.

In other applications it may be desirable to both adjust the PWM signal PWM-sig high time to achieve a target average current and/or a target pulse width, and also to adjust a delay time of the PWM signal PWM-sig to achieve accurate timing characteristics of the current Iled.

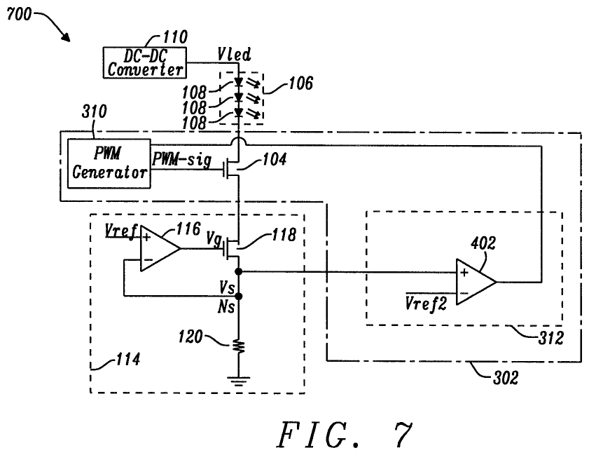

FIG. 7 is a schematic of an LED circuit 700 in accordance with a fifth embodiment of this disclosure. The LED circuit 700 corresponds to the LED circuit 400 with an alternative implementation of the feedback circuitry 312 shown. Common features between different Figures are represented by common reference numerals and common variables.

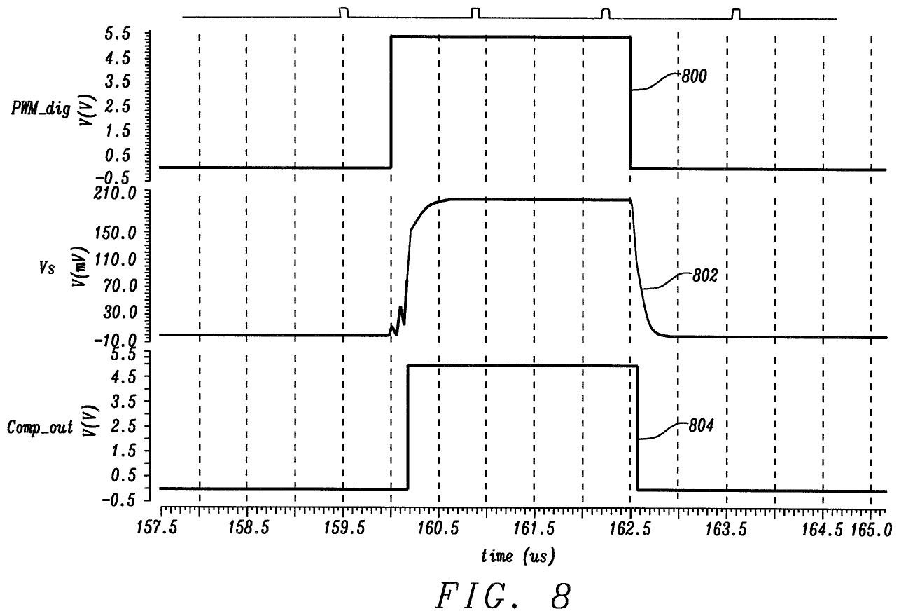

FIG. 8 shows simulation results relating to the LED circuit 700. The simulations were performed using parameters that are representative of a practical implementation of the LED circuit 700. Shown in FIG. 8 is the PWM signal PWM-sig 800, the node voltage Vs 802 and an output 804 of the comparator 402.

For the LED circuit 700, the rising and falling times of the node voltage Vs 802 are compliments of each other and as such the integrator circuits 404, 406, 407 described for the LED circuit 400 may be omitted.

The feedback circuitry 312 comprises the comparator 402.

In this specific example, the properties of the detected current Iled that are considered are the pulse width and the timing characteristics. In particular, with regards to the timing characteristics, the property is the turn on delay.

The current Iled is detected by detecting the node voltage Vs at the node Ns and providing the node voltage Vs to an input of the comparator 402. The other input of the comparator 402 receives a reference voltage Vref2. The reference voltage Vref2 is equal to half of the reference voltage Vref.

As the reference voltage Vref2 is equal to half the reference voltage Vref, the output 804 of the comparator 402 as shown in FIG. 8 provides a high signal to the PWM generator 310 when the current Iled is greater than or equal to half of its peak value. Therefore, a time period over which the comparator 402 outputs a high signal is the pulse width of the current waveform associated with the current Iled. Therefore, the comparator 402 outputs a signal that is suitable for the determination of the pulse width.

Additionally, the signal output by the comparator 402 is suitable for determination of the turn on delay. As the reference voltage Vref2 is equal to half the reference voltage Vref, the comparator 402 outputs a signal that transitions from a low state to a high state when the current Iled reaches half of its peak value as it rises, thereby providing a suitable signal for the determination of the turn on delay.

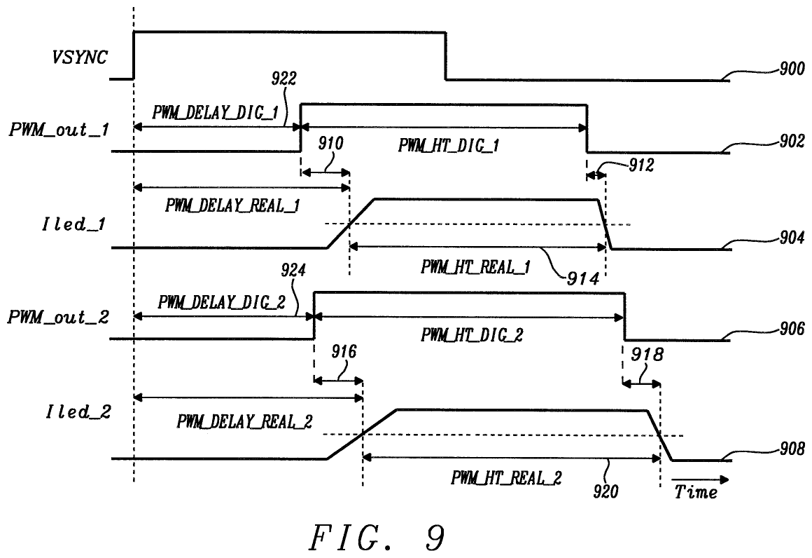

FIG. 9 is a graph showing waveforms relating to the operation of two LED circuits of the type shown in FIG. 7, where each LED circuit is synchronised using a VSYNC signal 900. The VSYNC signal 900 is a signal that is used to synchronise the on and off times of LEDs in LED backlighting applications.

FIG. 9 shows an output 902 of a PWM generator and a current Iled1 904 for a first LED circuit; and an output 906 of a PWM generator and a current Iled2 908 for a second LED circuit.

In such backlighting applications, different LEDs may have different turn on times. Different LEDs will have their brightness controlled by their associated PWM signal's PWM-sig high time.

The following parameters are shown on FIG. 9 for the first LED circuit: a turn on delay 910, a turn off delay 912, a pulse width 914; and for the second LED circuit: a turn on delay 916, a turn off delay 918, a pulse width 920. These parameters are as defined previously for FIG. 2: the turn on delay is the time taken from the PWM rising edge until the current Iled reaches half of its peak value; the turn off delay is the time taken from the PWM falling edge until the current Iled reaches half of its peak value; and the pulse width is the time period from when the current Iled is at half of its peak value, as the current Iled rises, until it returns to half of its peak value as the current Iled falls.

The high time PWM_HT_DIG of the PWM signal PWM-sig of the LED circuit 700 is given by equation (2) as described previously and is adjusted to provide a target pulse width. The target pulse width may be equal to the target high time setting PWM_HT_SET.

As discussed previously, in the present embodiment the signal output by the comparator 402 is suitable for determination of the pulse width of the current Iled. The compensation signal PWM_HT_COMP is determined by comparing the pulse width of the current Iled with the target pulse width provided by the user defined target high time setting PWM_HT_SET. The compensation signal PWM_HT_COMP is then used to adjust the high time PWM_HT_DIG to provide the target pulse width.

In this specific embodiment the compensation signal PWM_HT_COMP is determined by calculating the difference between the pulse width of the current Iled and the user defined target high time setting PWM_HT_SET, then passing the result through a proportional integral differential (PID) control loop to generate the compensation signal PWM_HT_COMP.

There may be a delay between the rising edge of the VSYNC signal 900 and a PWM rising edge, as shown by reference numerals 922 and 924. A delay time of the PWM signal PWM-sig is given by equation (6):

PWM_DELAY_DIG=PWM_DELAY_SET−PWM_DELAY_COMP (6)

where PWM_DELAY_DIG is the compensated delay time; PWM_DELAY_SET is the original PWM delay time, which may be set by a user and therefore may be representative of a target delay time; and PWM_DELAY_COMP is the compensation of the delay time. PWM_DELAY_DIG is represented by reference numerals 922 and 924 for the first and second LED circuits on FIG. 9.

As discussed previously, the timing characteristics of the current Iled may refer to the turn on and/or turn off delay. In this specific embodiment it is desirable to provide a compensated delay time PWM_DELAY_DIG that compensates for the turn on delay.

As discussed previously, in the present embodiment the signal output by the comparator 402 is suitable for determination of the turn on delay. The compensation signal PWM_DELAY_COMP is determined by comparing the turn on delay with the target delay time that is provided by the user defined PWM delay time PWM_DELAY_SET. The compensation signal PWM_DELAY_COMP is then used to adjust the compensated delay time PWM_DELAY_DIG to provide the target delay time and the desired timing characteristics of the current Iled.

The compensation signal PWM_DELAY_COMP may be derived by determining the turn on delay, as described above and passing the turn on delay to a digital low pass filter.

Additionally, the compensation signal PWM_HT_COMP may also be derived using a digital low pass filter. Digital low pass filters may be used to make one or both of the compensation signals PWM_DELAY_COMP, PWM_HT_COMP stable.

The LED circuit 700 can provide a target pulse width for the current Iled, but may provide an inaccurate average of the current Iled, when compared with the LED circuit 400. This is a result of variations in the rising and falling times of the current waveform of the current Iled. However, in some backlighting applications it is more desirable to provide a well-controlled and accurate pulse width than average current.

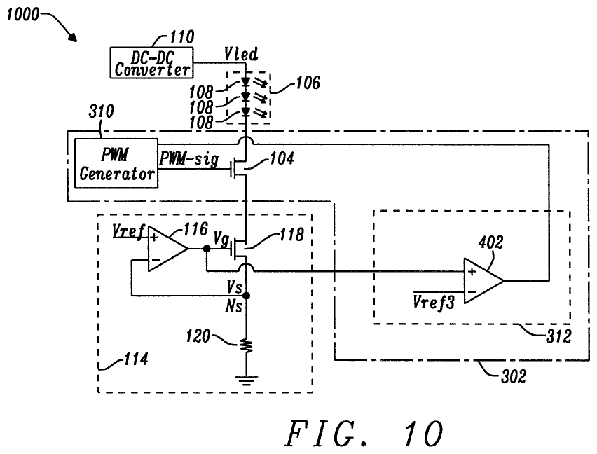

FIG. 10 is a schematic of an LED circuit 1000 in accordance with a sixth embodiment of this disclosure. The LED circuit 1000 corresponds to the LED circuit 700 but in the LED circuit 1000, the comparator 402 has a first input coupled to the gate of the regulator transistor 118 and has a second input coupled to a reference voltage Vref3. Common features between different Figures are represented by common reference numerals and common variables.

In this specific example, the property of the detected current Iled is the timing characteristics. In particular, with regards to the timing characteristics, the property is the turn on delay.

The current Iled is detected by detecting the gate voltage Vg of the regulator transistor 118. The reference voltage Vref3 is a gate threshold value Vth which is equal to the value at which the regulator transistor 118 is in an “on state”. The time between the PWM signal PWM-sig being received at the dimming transistor 114 and the comparator 402 outputting a high signal is the turn on delay T_turn_on. Therefore the signal output by the comparator 402 is suitable for determining the turn on delay T_turn_on.

As discussed previously for the LED circuit 316, detecting the gate voltage Vg does not provide a direct or precise measurement of the current Iled, however detecting the gate voltage Vg can provide an indication of the presence of the current Iled and therefore, detecting the gate voltage Vg is a suitable method for detecting the current Iled.

Having a suitable reference voltage Vref3, for example being equal to the gate threshold value Vth means that the comparator 402 outputs a high signal at a time that is approximately equal to the time at which the current Iled reaches half of its peak value. Therefore, the present embodiment provides a means of determining the turn on delay T_turn_on associated with the current waveform.

The LED circuit 1000 provides a simplified compensation method to detect the turn-on delay from the MOSFET gate terminal (the gate of the regulator transistor 118) by detecting the gate voltage Vg.

The present embodiment is used to compensate turn on delay only. As discussed previously, there are four factors relevant for comparing a PWM waveform to a current waveform as follows: turn on delay, turn off delay, rising time and falling time. Usually rising and falling times can compensate each other and turn off delay is much smaller than turn on delay, therefore turn on delay may be a dominant factor in the inaccuracy of the current waveform. Consequently, it is possible to estimate the pulse width and adjust the PWM signal PWM-sig accordingly, using only the turn on delay information.

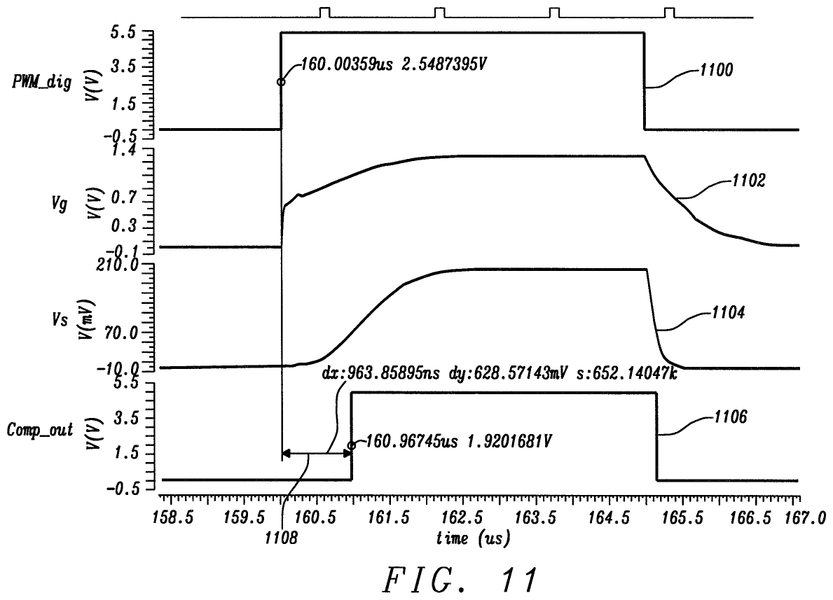

FIG. 11 shows simulation results relating to the LED circuit 1000. The simulations were performed using parameters that are representative of a practical implementation of the LED circuit 1000. Shown in FIG. 11 is the PWM signal PWM-sig 1100, the gate voltage Vg 1102, the node voltage Vs 1104 and an output 1106 of the comparator 402. The turn on delay T_turn_on is indicated by reference numeral 1108.

The high time of the PWM_HT_DIG of the PWM signal PWM-sig of the LED circuit 1000 is given by equation (7):

PWM_HT_DIG=PWM_HT_SET+T_turn_on. (7)

The delay time of the PWM signal PWM-sig is given by equation (8):

PWM_DELAY_DIG=PWM_DELAY_SET−T_turn_on (8)

It can be seen from equations (7) and (8) that the PWM signal PWM-sig may be adjusted using the turn on delay T_turn_on.

In the embodiments presented, the PWM signal PWM-sig may be adjusted by doing at least one of the following: increasing the high time of the PWM signal PWM-sig; decreasing the high time of the PWM signal PWM-sig; increasing a delay time of the PWM signal PWM-sig; or decreasing the delay time of the digital signal.

Various improvements and modifications may be made to the above without departing from the scope of the disclosure.

What is claimed is:

1. A pulse width modulation (PWM) circuit, comprising:
a switch for repeatedly coupling and decoupling a circuit element to a current source;
feedback circuitry configured to detect a current flowing through the circuit element; and
a PWM generator configured to provide a digital signal to the switch and to adjust the digital signal in response to the detected current.

2. The PWM circuit of claim 1, wherein:
the current source is configured to provide the current to the circuit element when the current source and the circuit element are coupled;
the digital signal comprises a first state and a second state;
the switch is arranged to couple the circuit element to the current source when the digital signal is in the first state; and
the switch is arranged to decouple the circuit element from current source when the digital signal is in the second state.

3. The PWM circuit of claim 1, wherein the switch is a dimming transistor comprising a gate coupled to the PWM generator, wherein the digital signal is received at the gate of the dimming transistor.

4. The PWM circuit of claim 1, wherein the circuit element comprises at least one light emitting diode (LED).

5. The PWM circuit of claim 1, wherein the current source comprises a current regulator.

6. The PWM circuit of claim 5, wherein the current regulator comprises:
an operational amplifier;
a regulator transistor; and
a setting resistor; wherein:
the operational amplifier has a first input coupled to a reference voltage, a second input coupled to a terminal of the regulator transistor at a node and an output coupled to a gate of the regulator transistor; and
the setting resistor has a first terminal coupled to the node and a second terminal coupled to ground.

7. The PWM circuit of claim 6, wherein the feedback circuitry is configured to detect the current flowing through the circuit element by detecting the current at the node.

8. The PWM circuit of claim 7, wherein the feedback circuitry is configured to detect the current at the node by detecting a node voltage at the node.

9. The PWM circuit of claim 6, wherein the feedback circuitry is configured to detect the current flowing through the circuit element by detecting a gate voltage at the gate of the regulator transistor.

10. The PWM circuit of claim 1, wherein the PWM generator is configured to adjust the digital signal based on the outcome of a comparison between a property of the detected current and a target value.

11. The PWM circuit of claim 10, wherein the feedback circuitry comprises:
a comparator for performing the comparison by comparing a signal that is representative of the property of the detected current with the target value.

12. The PWM circuit of claim 11, wherein the property of the detected current is the average of the detected current.

13. The PWM circuit of claim 12, wherein the feedback circuitry comprises:
an integrator circuit configured to provide the signal that is representative of the average detected current to the comparator.

14. The PWM circuit of claim 13, wherein the current source comprises a current regulator.

15. The PWM circuit of claim 10, wherein the property of the detected current is a pulse width.

16. The PWM circuit of claim 10, wherein the property of the detected current is a turn on delay.

17. The PWM circuit of claim 9, wherein the PWM generator is configured to adjust the digital signal using a property of the detected current, the property of the detected current being a turn on delay.

18. The PWM circuit of claim 17, wherein the feedback circuitry comprises:
a comparator for comparing the gate voltage with a third reference voltage to provide a signal suitable for determination of the turn on delay.

19. The PWM circuit of claim 1, wherein the PWM generator is configured to adjust the digital signal by doing at least one of the following:
increasing a high time of the digital signal;
decreasing the high time of the digital signal;
increasing a delay time of the digital signal; and
decreasing the delay time of the digital signal.

20. A method of operating a pulse width modulation (PWM) circuit, comprising:
repeatedly coupling and decoupling a circuit element to a current source using a switch;
detecting a current flowing through the circuit element using feedback circuitry; and
providing a digital signal to the switch and adjusting the digital signal in response to the detected current using a PWM generator.
